(19) United States
(12) Patent Application Publication
(10) Pub. No.: US 2026/0332127 A1
(43) Pub. Date: Oct. 22, 2026

(54) CROSSTALK CONTROL AND HIGH-POWER SIGNAL REJECTION IN QUANTUM SYSTEMS UTILIZING MONOLITHIC TUNABLE BANDSTOP FILTER

(71) Applicant: Dell Products L.P., Round Rock, TX (US)

(72) Inventors: Navjot Kaur Khaira, Manotick (CA); Tejinder Singh, Manotick (CA)

(21) Appl. No.: 19/186,356

(22) Filed: Apr. 22, 2025

(51) Int. Cl. H03H 11/04; H03K 17/92

(52) U.S. Cl. CPC H03H 11/04; H03K 17/92; H03H 2011/0488

(57) ABSTRACT

The technologies described herein are directed towards a tunable bandstop filter capable of operating at cryogenic temperatures. The bandstop filter includes respective capacitors, and respective inductors inductively coupled to respective RF-SQUID sets. The respective inductor inductances are controllable by applying a voltage to respective DC control lines inductively coupled to the respective RF-SQUID sets, which in turn are inductively coupled to the respective inductors. The controllably tuned inductance adjusts the frequency band that the bandstop filter attenuates. The tunable device attenuates noise frequencies to pass a cleaner microwave signal directed for interaction with qubits, for example, and improves overall qubit stability. In one example implementation, a classical computing device can be used to monitor the qubits following qubit interaction with a microwave signal from a photon source, detecting any deviations or noise-induced errors. Based on the monitoring, the computing device can adjust the bandstop filter's rejected frequency range.

### BACKGROUND

Quantum computing systems perform highly sensitive operations where even small amounts of noise can lead to significant errors during qubit manipulation. Traditional quantum systems, where signals from a photon source directly interact with the qubit chain, are particularly vulnerable to noise, resulting in decoherence and reduced gate fidelity. As quantum operations require long periods of coherence, errors introduced by noise and/or other environmental factors can accumulate, compromising quantum gate operations.

### BRIEF DESCRIPTION OF THE DRAWINGS

The technology described herein is illustrated by way of example and not limited to the accompanying figures in which like reference numerals indicate similar elements and in which:

FIG. 1 is a top view representation of an example tunable bandstop filter suitable for use with quantum hardware, e.g., with signal input from a microwave source and bandstop filtered output directed to qubits, in accordance with various example embodiments and implementations of the subject disclosure.

FIG. 2 is a three-dimensional (3D) representation of an example tunable bandstop filter layout, in accordance with various example embodiments and implementations of the subject disclosure.

FIG. 3 is a zoomed-in representation of a portion of the example tunable bandstop filter of FIG. 2, highlighting various components such as capacitor plates of a multilayer capacitor, and an rf-SQUID coupled inductor in accordance with various example embodiments and implementations of the subject disclosure.

FIG. 4 is a cross-sectional representation of the example bandstop filter device showing a multilayer superconducting fabrication process with eight superconducting thin films and six interconnects, in accordance with various example embodiments and implementations of the subject disclosure.

FIG. 5 is a top view representation of an example compact, tunable bandstop filter layout in which tuning of the bandstop filter is achieved by using an array of rf-SQUIDs, in accordance with various example embodiments and implementations of the subject disclosure.

FIG. 6 is a graphical representation of simulated transmission magnitude of the example tunable bandstop filter versus frequency for one example tunable bandstop filter, in accordance with various example embodiments and implementations of the subject disclosure.

FIG. 7 is a graphical representation of simulated reflection magnitude versus frequency for one example tunable bandstop filter, in accordance with various example embodiments and implementations of the subject disclosure.

FIG. 8 is a block diagram representation of an example a hybrid classical-quantum system in which a tunable bandstop filter is deployed in a dilution refrigerator before a qubit chain to filter a microwave signal directed towards the qubit chain, in accordance with various example embodiments and implementations of the subject disclosure.

FIGS. 9 and 10 depict an example hybrid classical-quantum system for controlling and measuring qubit operations, including via selectively tuned bandstop filtering of signal to qubits via a cryogenic tunable bandstop filter, in accordance with various example embodiments and implementations of the subject disclosure.

FIG. 11 is a conceptual representation of a quantum computer including a dilution refrigerator with qubits and a cryogenic tunable bandstop filter operating at qubit temperatures, in accordance with various example embodiments and implementations of the subject disclosure.

FIG. 12 is a flow diagram showing example operations related to controlling a tunable bandstop filter device to attenuate a frequency range to pass a radio frequency signal outside of the frequency range, in accordance with various example embodiments and implementations of the subject disclosure.

### DETAILED DESCRIPTION

The technology described herein is generally directed towards bandstop filters suitable for use in quantum systems, including at cryogenic temperatures. In general, bandstop filters, also known as notch filters or band-reject filters, are designed to attenuate or reject a specific range of frequencies while allowing frequencies outside this range to pass through with minimal attenuation. Because quantum computers are highly sensitive to electromagnetic interference and other forms of noise, which can occur at specific frequencies, by selectively rejecting these interfering frequencies, bandstop filters help maintain the purity of the microwave signals used to control and read out qubits, helping to ensure that the qubits remain in their desired quantum states. Additionally, bandstop filters protect sensitive quantum components from spurious signals generated by nearby electronics or external sources. For example, in cryogenic environments, spurious harmonics or noise from power supplies and control electronics can be particularly problematic. Bandstop filters can reject these specific frequencies, safeguarding the quantum system's integrity. Furthermore, bandstop filters are employed to prevent crosstalk between different qubits or between qubits and other components within the quantum processor.

Described herein is a microstrip-based tunable (e.g., two-pole) bandstop filter, such as with a center frequency 5 GHz and 100 MHz bandwidth, suitable for quantum applications. In one implementation, the tunable bandstop filter includes two metal-insulator-metal (MIM) capacitors, and two microstrip inductors inductively coupled with radio-frequency superconducting quantum interference devices (rf-SQUIDs) to achieve independent tunability of the inductance and, consequently, the real-time tuning of the stopband frequency. This design offers compactness and flexibility, making it appropriate for quantum systems.

Note that conventional microwave bandstop filters, while effective in some applications, present several challenges when used in quantum systems, including that conventional bandstop filters may introduce insertion loss, which can attenuate the desired signal alongside the rejected frequencies. Traditional filters can also introduce additional noise into the system, while quantum systems need extremely low-noise environments to maintain the quantum states of qubits. Size and footprint are another limitation, as traditional bandstop filters are often bulky and occupy significant space, which is a generally undesirable limitation in the highly compact and integrated environments of quantum computers. Conventional bandstop filters are typically designed with a fixed frequency response, which limits their flexibility; such fixed filters may not match the specific frequencies that need to be rejected, leading to suboptimal performance. Traditional bandstop filters are generally not optimized for cryogenic operation, where quantum computers typically function; components that work well at room temperature may perform poorly or inconsistently at cryogenic temperatures.

Indeed, traditional microwave bandstop filters for quantum systems primarily involve waveguide and lumped element filters designed to block specific frequencies that cause interference or noise within quantum computers. Waveguide filters, although effective in rejecting targeted frequencies, tend to be large and difficult to integrate into the compact cryogenic setups required for quantum operations. Lumped element filters, while more compact, often lack the precision and flexibility needed for quantum systems, as they typically operate at fixed frequencies and cannot easily adapt to changes in qubit frequencies. Furthermore, conventional bandstop filters can introduce insertion loss or additional noise, which can degrade quantum coherence.

The limitations of such traditional microwave bandstop filters are overcome by the more advanced, integrated, and tunable bandstop filtering device, capable of being deployed in quantum computing environments, described herein. The bandstop filter can be manufactured using a multilayer superconducting fabrication process, resulting in a highly integrated device with a compact footprint suitable for quantum computing applications. The technology described herein overcomes these drawbacks associated with conventional bandstop filters.

Reference throughout this specification to “one embodiment,” “an embodiment,” “one implementation,” “an implementation,” etc. means that a particular feature, structure, characteristic and/or attribute described in connection with the embodiment/implementation can be included in at least one embodiment/implementation. Thus, the appearances of such a phrase “in one embodiment,” “in an implementation,” etc. in various places throughout this specification are not necessarily all referring to the same embodiment/implementation. Furthermore, the particular features, structures, characteristics and/or attributes may be combined in any suitable manner in one or more embodiments/implementations. Repetitive description of like elements employed in respective embodiments may be omitted for sake of brevity.

The detailed description is merely illustrative and is not intended to limit embodiments and/or application or uses of embodiments. Furthermore, there is no intention to be bound by any expressed or implied information presented in the preceding sections, or in the Detailed Description section. Further, it is to be understood that the present disclosure will be described in terms of a given illustrative architecture; however, other architectures, structures, materials and process features, and steps can be varied within the scope of the present disclosure.

It also should be noted that terms used herein, such as “optimize,” “optimization,” “optimal,” “optimally” and the like only represent objectives to move towards a more optimal state, rather than necessarily obtaining ideal results. Similarly, “maximize” means moving towards a maximal state (e.g., up to some processing capacity limit), not necessarily achieving such a state, and so on.

It will also be understood that when an element such as a layer, region or substrate is referred to as being “on” or “over” “atop” “above” “beneath” “below” and so forth with respect to another element, it can be directly on the other element or intervening elements can also be present. In contrast, only if and when an element is referred to as being “directly on” or “directly over” another element, are there no intervening element(s) present. Note that orientation is generally relative; e.g., “on” or “over” can be flipped, and if so, can be considered unchanged, even if technically appearing to be under or below/beneath when represented in a flipped orientation. It will also be understood that when an element is referred to as being “connected” or “coupled” to another element, it can be directly connected or coupled to the other element or intervening elements can be present. In contrast, only if and when an element is referred to as being “directly connected” or “directly coupled” to another element, are there no intervening element(s) present.

The following detailed description is merely illustrative and is not intended to limit embodiments and/or application or uses of embodiments. Furthermore, there is no intention to be bound by any expressed or implied information presented in the preceding sections, or in the Detailed Description section.

One or more example embodiments are now described with reference to the drawings, in which example components, graphs and/or operations are shown, and in which like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details, and that the subject disclosure may be embodied in many different forms and should not be construed as limited to the examples set forth herein.

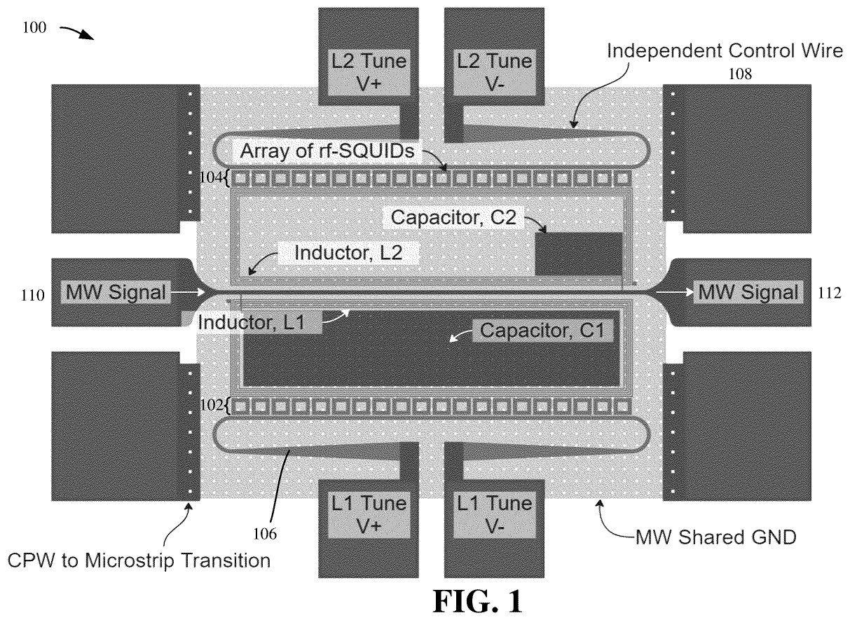

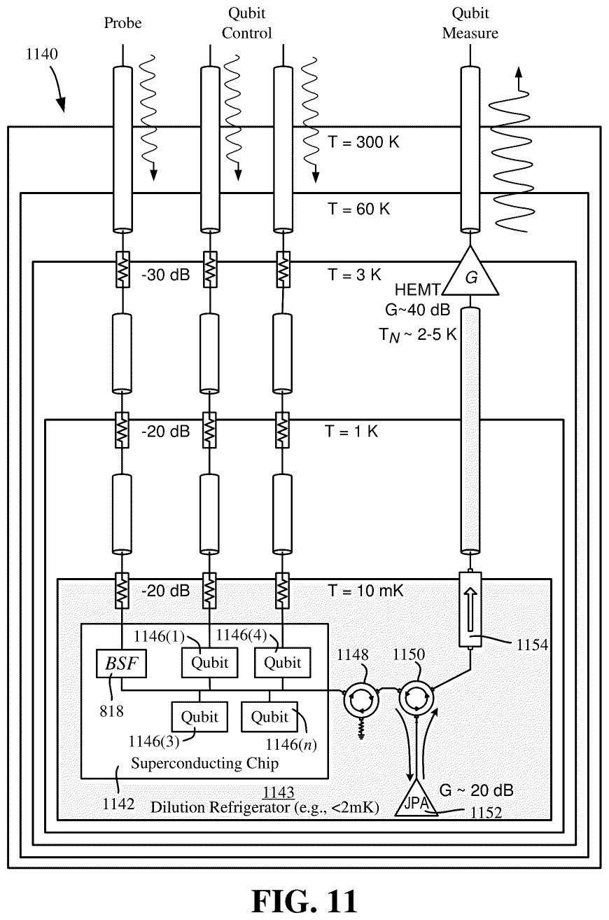

FIG. 1 shows one example of a microwave signal tunable bandstop filter 100 (FIGS. 1-5) suitable for use at cryogenic temperatures. In general, the tunable bandstop filter 100 described herein is directed to a bandstop filter with precise filtering control based on radio-frequency superconducting quantum interference device (RF-SQUID)-based superconducting. The example device can be deployed in a dilution refrigerator, and indeed, (as in FIG. 11), can be monolithically integrated on the same chip as the qubits, e.g., optimized for operation at extremely low cryogenic temperatures of around 2 mK.

A chip layout of the tunable two-pole bandstop filter is shown in FIG. 1. In one implementation, the design includes two metal-insulator-metal (MIM) capacitors, C1 and C2 (also known as parallel plate capacitors), and two microstrip inductors, L1 and L2. The values of L1, L2, C1, and C2 establish the filter's stopband within a defined frequency range. The two LC sets, starting with capacitors C1 and C2, are connected in shunt with the input-output microstrip.

To provide tunability, the inductors L1 and L2 are inductively coupled to arrays of rf-SQUIDs 102 and 104, respectively, that are deployed along one side of each of the microstrip inductors, L1 and L2. The rf-SQUIDs facilitate independent adjustment of the inductance values of L1 and L2, which in turn control the filter's frequency response. This is achieved by varying the magnetic flux threading the rf-SQUID loops. The flux is modulated (e.g., on chip) through independent control wires 106 and 108 running parallel and inductively coupled to the rf-SQUIDs 102 and 104, respectively, as shown in FIG. 1. For each inductor, L1 and L2, there are two control pads (L1 tune V+ and L1 tune V−, and L2 tune V+ and L2 tune V−) where voltage differences are applied, causing an independent change in the magnetic flux through each of the rf-SQUIDs 102 and 104 that depends on the applied voltages. This controlled voltage-induces flux change alters the loop inductance of the rf-SQUIDs 102 and 104, which is closely coupled to the microstrip inductors, ultimately tuning the filter's stopband.

Microwave photons enter and exit the filter through a coplanar waveguide (CPW) interface, which then transitions into for from a microstrip, as shown in FIG. 1. Note that this is only one possible nonlimiting example design; for example, the input and output can instead be directly connected to a microstrip. The independent filter tuning is achieved via the L1 V+ and L1 V− and the L2 V+ and L2 V− pads of the L1 and L2 tuning controls, respectively, such as by a computing device as described herein.

To derive the expression for the change in inductance of the microstrip inductor when coupled with RF-SQUIDs, consider a microstrip unit cell, which in an equivalent circuit includes a shunt capacitance Cₘ and series inductance Lₘ, coupled to a superconducting loop with inductance L_{sq} and Josephson Junction (JJ) with inductance Lⱼ. The coupling between Lₘ and L_{sq} is defined by mutual coupling M₁ and coupling coefficient K₁. Additionally, a microstrip control transmission line, monolithically integrated on-chip, runs parallel to the RF-SQUIDs. The unit inductance of this control microstrip transmission line L_{c} couples to the SQUID loop inductance L_{sq} with mutual inductance M₂ and coupling coefficient K₂.

$${K}_{1}^{2} = \frac{{M}_{1}^{2}}{{L}_{sq} {L}_{c}} ; {K}_{2}^{2} = \frac{{M}_{2}^{2}}{{L}_{sq} {L}_{c}} \qquad ( 1 )$$

The control current i_{dc} applied to the control line generates a magnetic field around the microstrip top conductor, inducing a geometrical flux φₑₓₜ in the SQUID loop:

$${ϕ}_{ext} = {M}_{2} {i}_{dc} \qquad ( 2 )$$

A circulating current i_{sq} is induced in the SQUID loop to screen this flux, due to flux quantization condition, leading to the total flux φ_{sq} in the loop:

$${ϕ}_{sq} = {ϕ}_{ext} + {L}_{sq} {i}_{sq} \qquad ( 3 )$$

The circulating supercurrent depends on the critical current I_{c} of the JJ and the total flux in the SQUID loop:

$${i}_{sq} = - {I}_{c} sin \frac{2 {πϕ}_{sq}}{{ϕ}_{0}} \qquad ( 4 )$$

where φ₀ is the flux quantum (φ₀=2.0679×10⁻¹⁵ Wb) and I_{c} is determined by the area of the junction A and the current density J_{c} of the junction. The behavior of the SQUID is characterized by the screening parameter of RF-SQUID given by:

$$β = \frac{2 π {L}_{sq} {I}_{c}}{{ϕ}_{0}} \qquad ( 5 )$$

For this application, the condition β<1 is satisfied, and the internal flux in the SQUID increases monotonically with the external flux φₑₓₜ.

SQUID inductance is a combination of the junction inductance and the inductance of the superconducting loop. The effective inductance controlled by modulating the magnetic flux threading the junction loop can be obtained as:

$${L}_{eff} = \frac{d {ϕ}_{ext}}{{di}_{sq}} \qquad ( 6 )$$

Differentiating equation (3) with respect to iₛ

$$\frac{d {ϕ}_{ext}}{{di}_{sq}} = - {L}_{sq} + \frac{1}{{di}_{sq} / d {ϕ}_{ext}} \qquad ( 7 )$$

Differentiating equation (4) with respect to φₛ

$$\frac{{di}_{sq}}{d {ϕ}_{ext}} = - \frac{2 π {I}_{c}}{{ϕ}_{0}} cos ( \frac{2 {πϕ}_{sq}}{{ϕ}_{0}} ) \qquad ( 8 )$$

Combining equations (5), (6), (7) and (8),

$${L}_{eff} = {L}_{sq} + \frac{{L}_{sq}}{βcos ( 2 {πϕ}_{sq} ) / {ϕ}_{0}} \qquad ( 9 )$$

$${L}_{eff} = {L}_{sq} + {L}_{j} \qquad ( 10 )$$

where Lⱼ is the junction equivalent inductance.

$${L}_{j} = \frac{{L}_{sq}}{βcos ( 2 {πϕ}_{sq} ) / {ϕ}_{0}} \qquad ( 11 )$$

The effective inductance of the microstrip inductor Lₘ′ coupled to the SQUID is influenced by the change in inductance from the RF-SQUIDs and the level of mutual coupling between the inductive microstrip and the four RF-SQUIDs.

$${L}_{m}^{′} = {L}_{m} [ 1 - \frac{{K}_{1}^{2} {L}_{sq}}{{L}_{j} + {L}_{sq}} ] = {L}_{m} [ 1 - \frac{{K}_{1}^{2}}{1 + ( \frac{1}{β} cos ( \frac{2 {πϕ}_{sq}}{{ϕ}_{0}} ) )} ]$$

The tunability in the inductance of the microstrip lines enabling precise control over the bandstop filter.

In one example implementation, as in FIG. 1 the bandstop filter is configured in a two-pole configuration, fabricated with a multilayer superconducting fabrication process that uses eight (e.g., Niobium) thin superconducting layers. Note that while two poles provide a desirable response, the bandstop filter technology described herein is not limited to a two pole device.

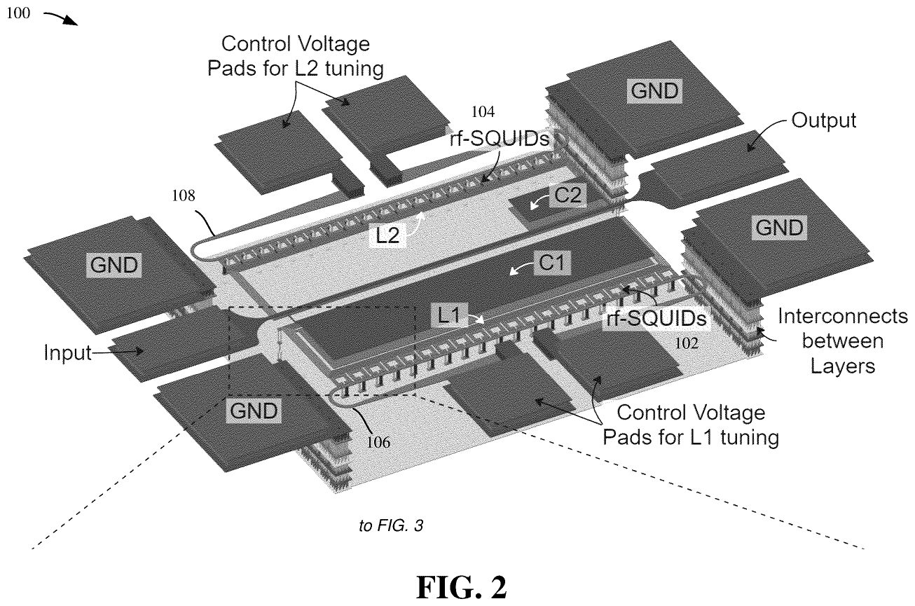

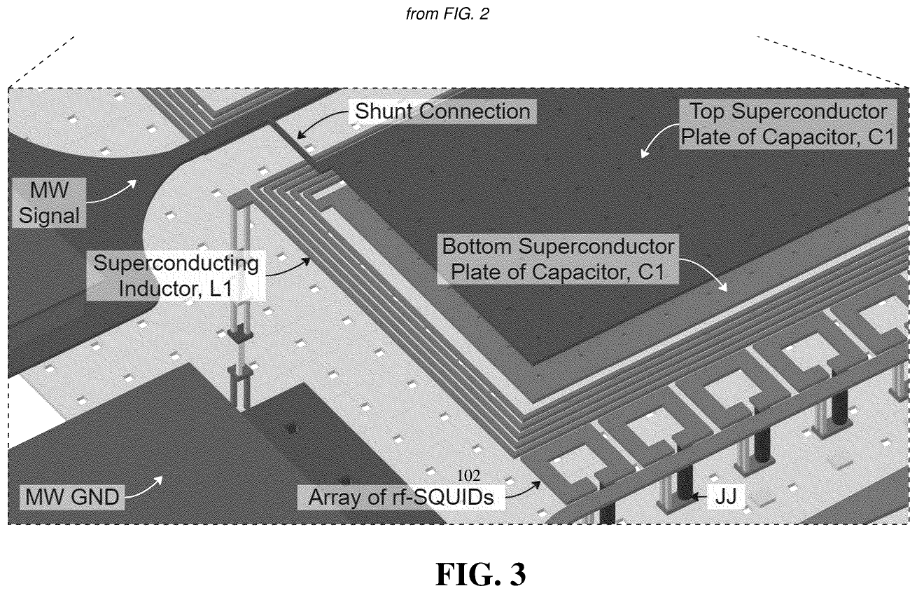

FIG. 2 is a three-dimensional view of the example bandstop filter with a zoomed-in portion shown in FIG. 3. FIGS. 2 and 3 together highlight the integration of rf-SQUIDs, superconducting inductors, MIM capacitors, and control voltage pads for tuning the L1 and L2 inductors. The multi-layer design ensures efficient space utilization. M ore particularly, FIGS. 2 and 3 show the integration of components to achieve a compact, tunable, and superconducting example bandstop filter 100. FIG. 3 zooms in on the top and bottom superconducting plates of the capacitor C1, and a portion of the array 102 of rf-SQUIDs that are positioned alongside the inductor L1. Each rf-SQUID in the array includes a Josephson Junction (JJ) tri-layer stack shunted by a superconducting square loop. The signal flow between components is managed by the interconnections between the layers while minimizing signal loss. This multilayer design results in efficient use of space and reduces the thermal load, a key consideration in quantum systems.

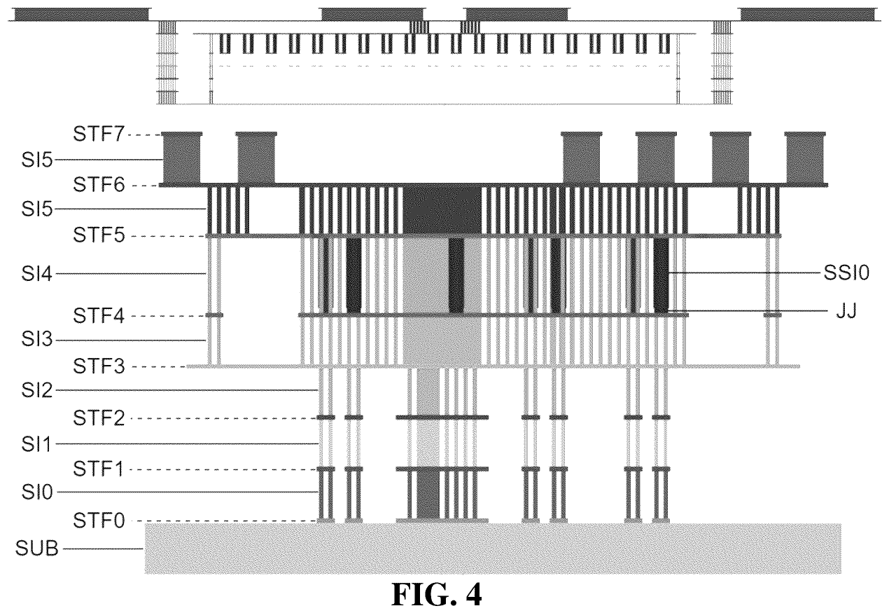

The example bandstop filter 100 can be manufactured using a sophisticated multilayer superconducting fabrication process, as depicted in the cross-sectional image in FIG. 4. The layer heights are intentionally scaled in the Z-direction for better visibility. The multilayer design incorporates eight superconducting thin films (STF0-STF7) interconnected by six superconducting interconnects (SI0-SI5), which facilitates efficient signal routing within a compact structure. A feature of this architecture is the integration of a tri-layer Josephson Junction (JJ) stack between layers STF4 and STF5, accessed through a dedicated superconducting interconnect (SSI0). This advanced fabrication process ensures that the bandstop filter is highly integrated and compact, making it well-suited for quantum computing environments.

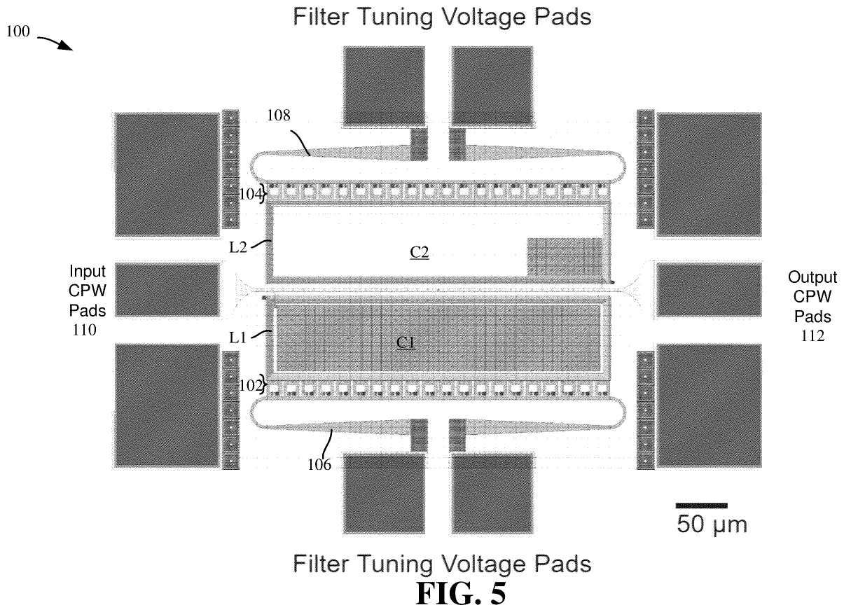

The layout of the example tunable bandstop filter 100 is shown in FIG. 5 and is optimized for operation in cryogenic environments. The bandstop filter design layout, as shown in FIG. 5, illustrates the compact and efficient use of space, significant for quantum systems where space is at a premium; a 50 micrometer (μm) length is depicted in this example to demonstrate the overall size of the example device. The bandstop filter 100 offers high precision in filtering specific frequency bands, and is compatible for fabrication using superconducting microfabrication process as shown in FIG. 4. The layout clearly highlights the primary contact points for user interaction, including the input coplanar waveguide (CPW) pads 110 where the microwave signal is injected and the output CPW pads 112 where the filtered signal is retrieved. The tunability of the filter response of the filter 100 is achieved by applying voltage differences across the sets of dedicated tuning voltage pads, respectively.

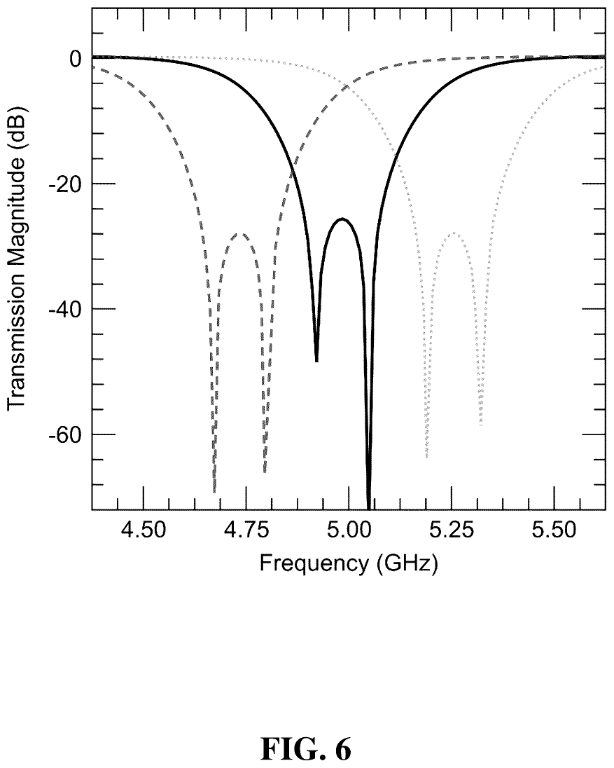

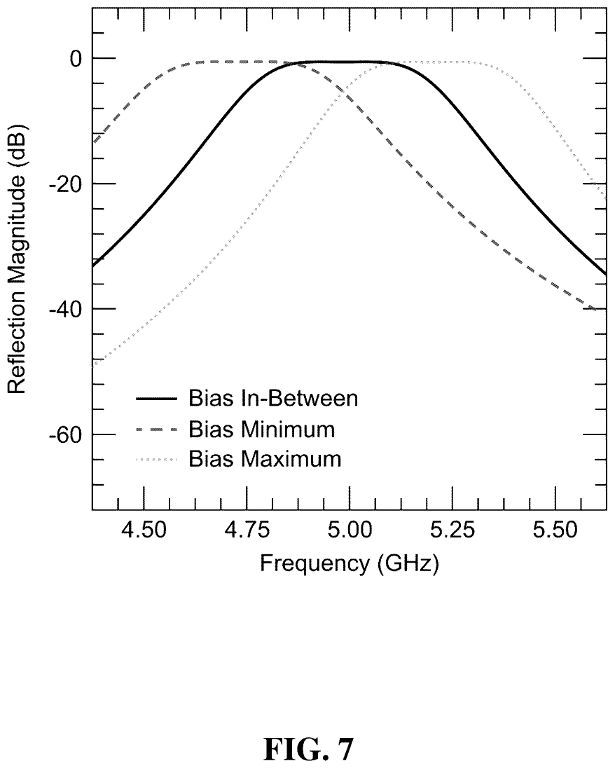

The plots in FIGS. 6 and 7 show the simulated frequency response of the bandstop filter between 4.5 GHZ-5.5 GHz in the transmission (S₂₁) and reflection (S₁₁) modes, respectively. In FIG. 6, the stopband is clearly defined, with strong attenuation in the stopband and minimal out-of-band insertion loss.

Each curve corresponds to a different tuning state achieved through the rf-SQUID array. The dotted and dashed curves illustrate how the rf-SQUIDs alter the stopband in response to changes in inductance. The reflection plot in FIG. 7 also shows the peaks for the respective tuning states, corresponding to stopband frequencies; the shift in reflection peaks indicates the changes in center frequency and bandwidth with the application of voltage bias. The tunability ensures that the filter can be precisely aligned to the frequency of the interference that needs to be removed.

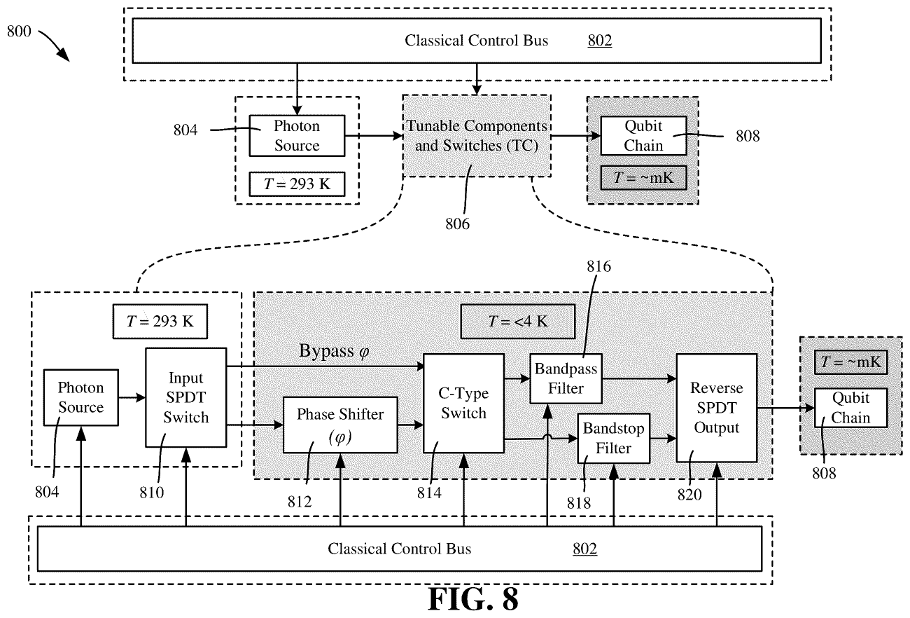

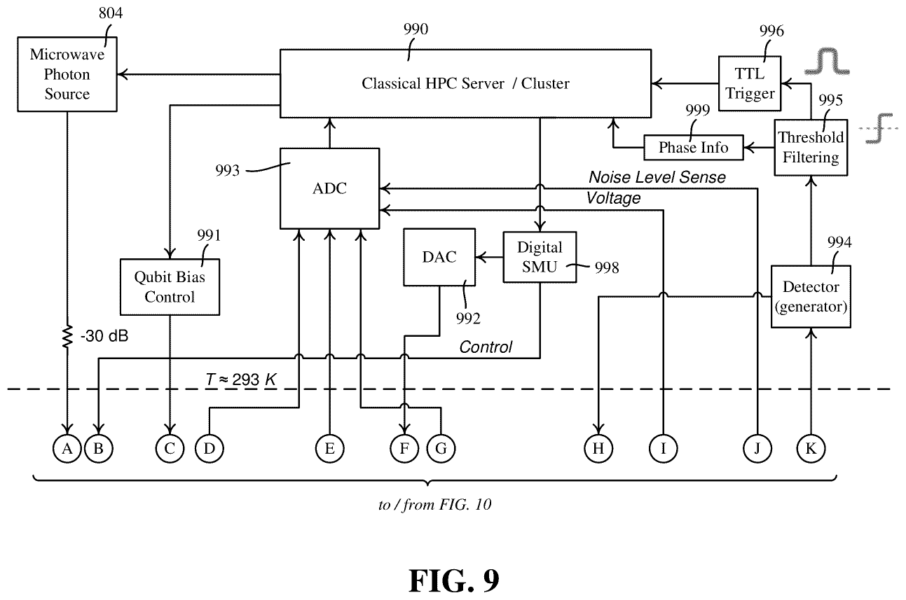

Turning to one example usage scenario, FIG. 8 is a generalized representation of an example hybrid classical-quantum system 800 that includes a classical control bus 802 (coupled to a classical computing device, e.g., FIG. 9) and a quantum circuit in which a photon source 804, tunable components and switches (TC) 806 and qubit chain 808 interact with the benefit of intermediate tunable components 806 as described herein. Note that the tunable components 806 make the qubits less vulnerable to noise, thermal drift, or other forms of signal degradation; indeed, such signal issues can lead to errors in qubit manipulation, reducing gate fidelity.

The photon source 804 generates the microwave signals used to manipulate qubits, as controlled by the computing device (the control bus 802 of which is shown in FIG. 8); the temperature at this stage is room temperature (e.g., around 293 K). The tunable components and switches 806 include an input single-pole, double throw (SPDT) switch 810 controlled via the classical control bus 802 to either bypass a phase shifter or shift the phase of the microwave signal via a phase shifter 812 that operates at cryogenic temperatures (below 4 K in this example). The phase shifter 812, if switched in, adjusts the phase of the microwave signals before they interact with the qubits of the qubit chain 808; the phase shifter may be a tunable device. The placement at cryogenic temperatures helps reduce phase drift caused by thermal noise.

A controlled C-type switch 814 selects a tunable (via the control bus 802) bandpass filter 816 as described herein, and/or a tunable bandstop filter 818 (e.g., corresponding to the bandstop filter 100 of FIGS. 1-5). A reverse SPDT switch 820 couples the filtered signal to the qubit chain 808.

The qubit chain 808 includes qubits that are maintained at extremely low temperatures (millikelvin range) to ensure their stability/coherence during quantum gate operations. The signals from the photon source 804 interact directly with the qubits, manipulating their quantum states. After interacting with the qubits, the signal can be amplified, and measured (e.g., at room temperature); the amplified and measured signals are processed at room temperature by the classical computing device, such as to adjust the phase shifter and/or filtering to correct for phase noise, frequency noise, and so on to maintain qubit coherence.

In general, the integration of the classical computing device (control node) can monitor the signals in real time, to detect any noise errors or deviations that arise due to external environmental factors or hardware imperfections. Because quantum gate operations are extremely sensitive to such noise-related variations, the classical computing device compares the incoming signals as measured and flags any discrepancies from what the signal should be without noise errors or the like. Upon detecting deviations, the control node dynamically adjusts the tunable components to correct the next signal before it interacts with the qubit chain, thereby minimizing the impact of noise on qubit operations.

Note that temperature control is a significant part of the quantum portion of the system, as different components operate at significantly different temperature levels to minimize noise and maintain coherence. The quantum processor operates at extremely low temperatures, with the qubit chain at 10 mK or below, and the signal amplifier at 30 mK. These temperatures maintain superconductivity and prevent thermal noise from disrupting the delicate quantum states. The flux sensing and control lines that interact with the qubits are also cooled down to 1 K to ensure minimal noise and stable control of the quantum operations. The classical control components, such as the microwave photon source, SMU, ADC, DAC, and HPC cluster, operate at room temperature (around 293 K). These components handle the classical data processing and control signals that drive the quantum system.

Via the tunable signal control and classical monitoring feedback loop, the system effectively mitigates noise, ensuring that the signals interacting with the qubits are phase-aligned and coherent throughout the gate operations. The cryogenic placement of the tunable components 806 minimizes thermal noise and drift, further enhancing the system's ability to maintain coherence. The combination of real-time control and error monitoring by the classical node ensures that qubits remain stable during computation, resulting in higher-fidelity quantum gate operations and improved overall performance of the quantum system. The technology described herein thus overcomes a significant challenge in quantum computing, namely preserving qubit coherence and reducing errors during quantum operations.

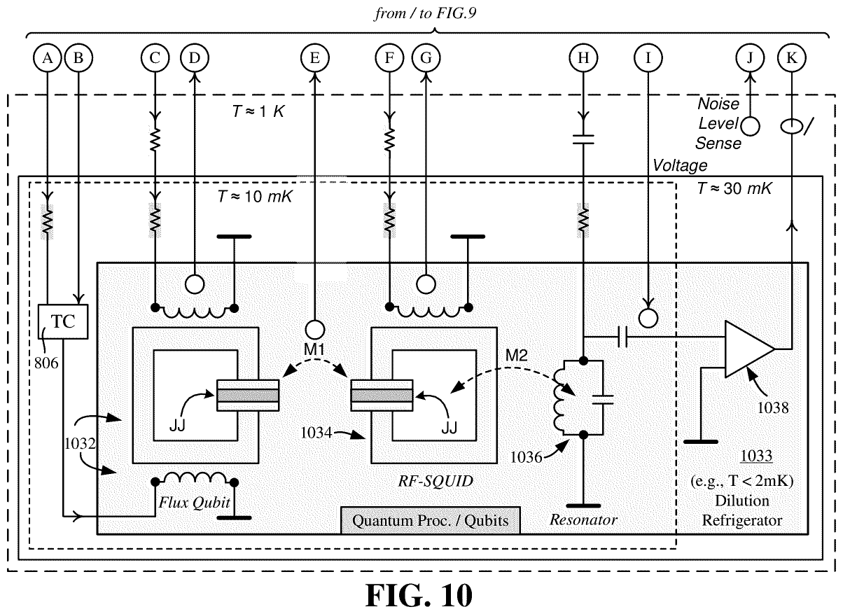

FIGS. 9 and 10 comprise a block diagram representation of an example quantum processor measurement and control setup/environment, in which qubit control and readout is facilitated by integrating a classical high-performance computing server/cluster 990 (FIG. 9) with a quantum computing system having a quantum processor and qubits 1032 (FIG. 10) near the base plate of a dilution refrigerator 1093, on the order of 2 milli-Kelvin (mk).

The representation of FIG. 10 thus shows an example architecture of a quantum system with a focus on cryogenic control and signal processing. The overall system (e.g., summarized in FIG. 8) integrates classical control components (FIG. 9) and quantum hardware (FIG. 10) to ensure the proper manipulation and measurement of qubits, with an emphasis on temperature management to maintain the coherence of quantum operations. As generally shown in FIG. 10, the quantum hardware is housed within the dilution refrigerator 1033, ensuring ultra-low temperatures for stable qubit operations. In one implementation, the quantum portion (FIG. 10) of the hybrid system 800 (FIG. 8) operates with a combination of flux qubits, RF-SQUIDs (radio frequency-superconducting quantum interference devices), and a resonator, each contributing to the manipulation and control of quantum states.

In general, a flux qubit is a type of qubit that operates based on superconducting loops in which the current can circulate in both clockwise and counterclockwise directions, representing quantum superposition. The qubit (e.g., 1032) is housed at a temperature of 10 mK or below (e.g., 2-4 mK), which helps maintain coherences and prevent decoherence due to thermal noise.

The RF-SQUIDs are superconducting circuits used to control the coupling between qubits. The RF-SQUIDs allow manipulation of quantum states by providing a tunable inductive coupling between the qubits. The Josephson junctions (JJ) in the RF-SQUIDs enable quantum tunneling, which is a core part of quantum operations in superconducting qubits. The magnetic interaction between the RF-SQUIDs (represented by M1), and between the RF-SQUID 1294 and the resonator 1296 (represented by M2), can adjust the energy levels and state transitions of the qubits.

The resonator 1036 is coupled to the qubits, providing a device to read out the qubit states. By measuring the resonance frequency shifts, the state of the qubits can be inferred, allowing for quantum state measurements. After interacting with the qubits, the signal is passed through a cryogenic amplifier 1038, e.g., operating at around 30 mK. Amplifying the signal in such a low-temperature environment ensures that noise is kept to a minimum before the signal is sent for classical processing. The amplifier 1038 helps to boost the weak quantum signals for subsequent measurement without introducing significant noise that could affect accuracy.

As shown in FIG. 9, the example classical (non-quantum) portion of the hybrid system 800 (FIG. 8) includes the microwave photon source 802, which is controlled by the classical high-performance compute (HPC) server/cluster 990, both operating at room temperature (around 293 K). As described herein, the classical system portion interfaces with the quantum hardware to drive, control, and measure qubit operations. M ore particularly and as will be understood, the server/cluster 990 processes the data from the quantum hardware, including measurements from the qubits, and can also provide real-time feedback for qubit control, adjusting the parameters, including the tunable components 806 (e.g., the bandstop filter 818), based on the measured outcomes to optimize the quantum operations.

The microwave photon source 804 generates microwave signals that interact with the qubits. The microwave source 804 feeds microwave signals through coaxial cables into the quantum hardware. The microwave signals are controlled to ensure precise phase, amplitude, and timing, as is appropriate for quantum gate operations. The microwave photons from the microwave photon source 804 go through multiple temperature stages to reach the flux qubits (e.g., 1232) in the dilution refrigerator 1233.

At each stage, along with the reducing temperature, the microwave signal is heavily attenuated as qubits are provided very low-power microwave photons. Note that the HPC server/cluster 980 can control operation of the photon source 804 in terms of pulses, e.g., the sequence of pulses, the width and voltage of the pulses and the like can be controlled by the classical server/cluster 980; any amount of gates can be applied to the qubit, to control the qubit and configure the qubit, including as described herein.

A qubit bias control component (block 991, FIG. 9) provides precise magnetic flux control to the qubits. Adjusting the magnetic flux through the superconducting loops enables the fine-tuning of the qubit states. This control system operates at room temperature but communicates with the cryogenic quantum hardware through superconducting lines. The qubit bias control can be in the form of a constant voltage or current to adjust the energy levels of the qubit, and can be provided from the classical HPC server/cluster 990. A change in the magnetic flux in the qubit 1032 (FIG. 10, after absorption of a photon) induces a change in the mutual flux coupling (M1) with an RF-SQUID M2, which in general acts as a detector controlled by the server/cluster 990, e.g., via a digital-to-analog converter (DAC) 992. The RF-SQUID 1232 includes a superconducting loop across a Josephson Junction (JJ) characterized by its critical current (IC), capacitance (C), and shunt resistance (R).

Note that in general, the digital-to-analog converter 992 along with an analog-to-digital converter (ADC) 993 translates between the digital signals used for classical computation and the analog signals used in the quantum hardware. The DAC 992 generates precise analog control signals for driving qubit operations, while the ADC 993 digitizes the analog signals received from the qubit measurement. These converters operate at room temperature in this example.

To register signals in RF-SQUIDs, a readout resonator/LC (inductor-capacitor) tank circuit 1036 (FIG. 10) is used, including an inductor (L_{T}) and a capacitor (C_{T}), which together oscillate at a natural frequency ω_{T}/2π=½π\sqrt{(L_{T}C_{T})}. The resonator 1036 is designed to be sensitive to small changes in magnetic flux, mutually coupled (M2) to the RF-SQUID 1034, as appropriate for detecting photon interactions with the qubit. An external pumping current I_{rf} sin(ω_{P}t) is provided (via labeled circle “G”) from a detector/generator 994 (FIG. 9) at frequency Ω/2π, which is very close to the natural frequency of the LC tank circuit resonator 1036 (ω_{P}−ω_{T})/ω_{T}<<1 and quality factor Q>>1. The current/voltage bias to the RF-SQUID 1036 is very accurate so as not to (inadvertently) operate the RF-SQUID M2 in non-hysteresis mode.

Note that FIG. 10 only shows components for two RF-SQUIDS/qubits, however any practical number may be present in a given quantum computing configuration. Further note that the resonator 1036 can obtain a control signal, and because any voltage generates the magnetic flux, a qubit state change will occur, as the generated magnetic flux will break the entanglement, or it will collapse the qubit; the system can read that what was the recent data, such as how much frequency changed in the resonator 1036.

The output from the LC tank/resonator 1036 is very weak, and hence is amplified (signal amplifier 1038) and provided to the detector 994 (FIG. 9), which further performs threshold filtering (block 995) to quantize the state of the qubit, and provides the transistor-transistor logic (TTL) trigger (block 996) to the classical server/cluster 990. In general, threshold filtering component, block 995, along with the detector 994, are part of the classical control system and fed to the PCIe interface, and are responsible for analyzing the output from the quantum hardware. The signals are passed through the threshold filter to remove noise and isolate the meaningful quantum information. The detector 994 then extracts the final measurement results from the filtered signals. The TTL trigger 996 is used for synchronizing operations within the classical system and with the quantum hardware. Precise timing of signals is used in quantum systems, and the TTL trigger 996 ensures that operations such as qubit state initialization, manipulation, and readout are synchronized.

To ensure accurate control, a PCIe card interface-based digital source measure unit (SMU) 998 can be used, such as a high-performance SMU that is commercially available. In general, a digital source measure unit (SMU) 998 provides precise voltage or current control for various elements in the quantum system. The SMU 998 ensures that bias voltages and other control parameters are stable, which maintains qubit fidelity. A high-performance PXI-based SMU (PCI eX tensions for Instrumentation) provides fast, precise dynamic measurements from DC to a 20 μs pulse, with outputs up to 210 V/315 mA, 10 femtoampere (fA) resolution, and the lowest source noise.

Similarly, a commercially available PXI-based digital-to-analog converter (DAC) 992 can be used, such as one that features sixteen simultaneous channels capable of supplying stimulus waveforms with output voltages ranging from 0V to +30V, and output currents from 0 mA to +20 mA. In one implementation, both the SMU 998 and DAC 992 are compatible with PCIe interfaces and can be housed in a PXI chassis, which saves rack space and reduces maintenance cost. Also shown in FIG. 11 is the analog-to-digital converter (ADC) 993 coupled to the classical server/cluster 1112 and a number of sensors (the small circles at various tap points in FIG. 10, corresponding to the circled labels D, E, G, I and J).

To summarize, in one example implementation, the digital SMU 998 can control tunable components 806 (FIGS. 8-10, including the bandstop filter 818) that can apply a filtered microwave signal to a qubit. Feedback information (block 999, FIG. 11) can be provided to the classical server/cluster 1112. Such feedback information allows real-time tuning and repeated measurements to ensure accurate quantum state tracking and error correction, e.g., if small deviations are detected between the applied signal and the measured signal following execution of one or more operations on the qubit as described herein, the signal can be adjusted and the operations reattempted and remeasured.

Thus, as generally represented in FIG. 11, hardware for control and readout can, for example, include one or more advanced source measure units (SMUs) and analog-to-digital converters (ADCs), which can be managed more efficiently with classical systems, thereby reducing the number of physical components and vendor equipment otherwise needed. Such a hybrid system can be designed modularly, where each module, including multiple qubits and their respective control/readout lines, can be independently managed by one or more classical processors. Such modularity simplifies system scaling, allowing new modules to be added without redesigning the entire control infrastructure.

The technology described herein leverages the precise classical control of the qubit control and measurement operations. For example, a classical high-performance computing server (or cluster of such servers) with peripheral component interconnect express (PCIe-based) or the like control can use a source measure unit (SMU) for quantum computers with some practical number (e.g., one the order of dozens) of qubits, including to apply controlled phase shift, controlled bandstop filtering, and controlled rotation to a qubit.

Further, the technology described herein controls the qubit readout circuit using a source measure unit and digital-to-analog converter; this can provide ultra-precise control of readouts with ultra-low signals. The hybrid classical-quantum technology described herein is, in part, directed to recording a photon-induced transition in a flux qubit, for example. Note however that photons/flux qubits are only examples, as indeed, the technology described herein is agnostic to any particular type of qubit, and further, that probe signals other than those based on microwave photons can be used, as appropriate for a given type of qubit.

Further, in one or more example implementations, a bandstop filter 818 can be designed and monolithically integrated with a superconducting chip that integrates the qubits. FIG. 11 is a block diagram representation of an example quantum processor measurement and control setup/system 1140 including a measurement and control setup for a superconducting quantum computing chip 1142 near the base plate of a dilution refrigerator 1143, on the order of 2-10 Kelvin (mK). Some number of qubits 1146(1)-1146(n) (four are depicted, but any practical number may be present) are fabricated on the superconducting quantum computing chip 1142, along with a monolithically integrated bandstop filter (BSF) 818. Note that the other tunable components 806 (FIG. 8, including the phase shifter 812 and/or the bandstop filter 818) also can be similarly fabricated on the superconducting quantum computing chip 1142.

Also shown in FIG. 11 as part of the qubit measuring portion are circulators 1148 and 1150, a Josephson parametric amplifier (JPA) 1152, an isolator 1154 and a high electron mobility transistor (HEMT) G. In general, a probe signal that is a set of strongly attenuated microwave tones (<−120 dBm) is by injected via coaxial cables (depicted as unshaded cylinders) and attenuators to the qubits 1146(1)-1146(n) through the various levels of the quantum processor system 1140, resulting in a measurement signal being input via a readout line to a first port of the circulator 1148. As described herein, the circulator 1148 is configured for clockwise rotation, whereby the signal is routed to a second port (low insertion loss) and not the third port (high isolation, and coupled via resistor to ground), nor returned to the first port (low return loss). The second port is coupled to the input port of a second circulator 1150 configured for counterclockwise rotation, such that the signal is routed to at least one Josephson parametric amplifier (JPA) 1152, with the amplified measurement signal routed back to the output port of the circulator 1150 though the isolator 1154 to the HEMT G for further gain before measurement by one or more conventional RF devices (not explicitly shown). Note that the shaded cylinder shown in the measurement signal output path represents a superconducting coaxial cable. Based on the measurement results, qubit control signals can be sent to the qubits 1146(1)-1146(n).

Thus, each circulator is a nonreciprocal three-port device that allows signals to travel in only one predetermined direction among its three ports, whereby the qubit readout line uses such circulators 1148 and 1150 to provide isolation between different components so as to maintain the fidelity of the qubit readout. By isolating different parts of the readout circuit, circulators help in reducing noise that could otherwise affect the qubit's state and/or the accuracy of the readout. Multiple circulators are used in the quantum computing setup, ensuring that signals are correctly channeled to the appropriate destinations as shown in FIG. 11.

To summarize FIG. 11, the state of the superconducting qubits is probed, and the readout involves amplifying and delivering the measured result back to room temperature. The weak output signal from a qubit is amplified using one or more superconducting parametric amplifiers, such as Josephson parametric amplifiers (JPA), operating at 10 mK and semiconductor high electron mobility transistor (HEMT) amplifiers operating at 4 K. The RF circulators are used to protect the quantum circuit from reflections and noise; the probing, control, and readout of qubit systems involves a large amount of microwave hardware.

One or more example implementations and embodiments can be embodied in a tunable bandstop filter, such as described and represented herein. The tunable bandstop filter can include a first microstrip inductor, a first capacitor, and a first RF-SQUID set; the first RF-SQUID set can be inductively coupled to the first inductor and inductively coupled to a first DC control line. The tunable bandstop filter can include a second microstrip inductor, a second capacitor, and a second RF-SQUID set; the second RF-SQUID set can be inductively coupled to the second inductor and inductively coupled to a second DC control line. A first amount of voltage applied to the first DC control line inductively couples a first amount of magnetic flux to the first RF-SQUID set, to determine a first controlled inductance of the first microstrip inductor, and a second amount of voltage applied to the second DC control line inductively couples a second amount of magnetic flux to the second RF-SQUID set, to determine a second controlled inductance of the second microstrip inductor. A radio frequency (RF) signal input to the tunable bandstop filter results in a filtered instance of the RF signal output from the tunable bandstop filter, within a controlled frequency range based on a first capacitance value of the first capacitor, the first controlled inductance of the first microstrip inductor, a second capacitance value of the second capacitor, and the second controlled inductance of the second microstrip inductor.

The RF signal can include a microwave signal output from a microwave signal source and directed towards a qubit chain.

The tunable bandstop filter and the qubit chain can be deployed within a dilution refrigerator.

The tunable bandstop filter and at least one qubit of the qubit chain can be fabricated on a single chip.

The tunable bandstop filter and the microwave signal source can be deployed at room temperature.

The first capacitor can include a first multilayer metal-insulator-metal capacitor, and the second capacitor can include a second multilayer metal-insulator-metal capacitor.

Layers of the first multilayer metal-insulator-metal capacitor can include niobium superconducting layers.

The amount of voltage applied to the DC control line can be controlled by a controller.

The controller can include a computing device that can include at least one processor and at least one memory.

The radio frequency signal can include a microwave signal directed towards a qubit, and the computing device can determine the first amount of voltage and can determine the second amount of voltage based on monitoring interaction of a previous filtered instance of a previous microwave signal with the qubit.

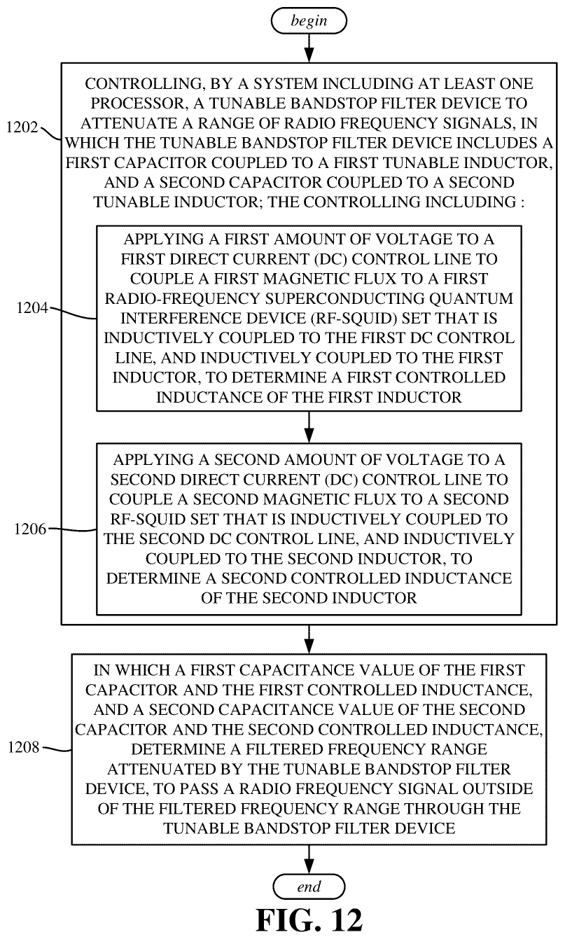

One or more example implementations and embodiments, such as corresponding to example operations of a method, can be represented in FIG. 12. Example operation 1202 represents controlling, by a system including at least one processor, a tunable bandstop filter device to attenuate a range of radio frequency signals, in which the tunable bandstop filter device includes a first capacitor coupled to a first tunable inductor, and a second capacitor coupled to a second tunable inductor. The controlling can include example operations 1204 and 1206. Example operation 1204 represents applying a first amount of voltage to a first direct current (DC) control line to couple a first magnetic flux to a first radio-frequency superconducting quantum interference device (RF-SQUID) set that is inductively coupled to the first DC control line, and inductively coupled to the first inductor, to determine a first controlled inductance of the first inductor. Example operation 1206 represents applying a second amount of voltage to a second direct current (DC) control line to couple a second magnetic flux to a second RF-SQUID set that is inductively coupled to the second DC control line, and inductively coupled to the second inductor, to determine a second controlled inductance of the second inductor. Example block 1208 represents that a first capacitance value of the first capacitor and the first controlled inductance, and a second capacitance value of the second capacitor and the second controlled inductance, determine a filtered frequency range attenuated by the tunable bandstop filter device, to pass a radio frequency signal outside of the filtered frequency range through the tunable bandstop filter device.

The radio frequency signal can include a microwave signal directed towards a qubit, and controlling the tunable bandstop filter device can be performed by a computing device that monitors interaction of a microwave signal with the qubit.

The filtered frequency range can be a first filtered frequency range, the radio frequency signal outside of the filtered frequency range can be a first radio frequency signal outside of the first filtered frequency range, and controlling the tunable bandstop filter device can be a first controlling operation to pass the first radio frequency signal outside of the filtered frequency range through the tunable bandstop filter device. Further operations can include, in a second controlling operation, controlling, by the system, the tunable bandstop filter device; the second controlling operation can include applying a third amount of voltage to a first direct current (DC) control line to couple a third magnetic flux to the first RF-SQUID set that can be inductively coupled to the first DC control line, and inductively coupled to the first inductor, to determine a third controlled inductance of the first inductor, and applying a fourth amount of voltage to the second direct DC control line to couple a fourth magnetic flux to the RF-SQUID set that can be inductively coupled to the second DC control line, and inductively coupled to the second inductor, to determine a fourth controlled inductance of the second inductor. The first capacitance value of the first capacitor, the third controlled inductance of the first inductor, the second capacitance value of the second capacitor, and the fourth controlled inductance of the second inductor, can determine a second frequency range attenuated by the tunable bandstop filter device, to pass a second radio frequency signal outside of the second filtered frequency range through the tunable bandstop filter device.

The first radio frequency signal can include a microwave signal directed towards a qubit.

The second controlling operation of the tunable bandstop filter device can be performed by a computing device that monitors interaction of the first microwave signal with the qubit, and the second controlling operation can be based on monitoring, by the system, the interaction of the first microwave signal, outside of the filtered frequency range and passed through the tunable bandstop filter with the qubit, to determine the third amount of voltage and the fourth amount of voltage.

One or more example implementations and embodiments can be embodied in a system, such as described and represented herein. The system can include a cryogenic tunable bandstop filter device, including a first capacitor, a first microstrip inductor electrically coupled to the first capacitor, a first RF-SQUID set inductively coupled to the first microstrip inductor, a second capacitor, a second microstrip inductor electrically coupled to the first capacitor, and a second RF-SQUID set inductively coupled to the second microstrip inductor. The system can include a controller configured to apply a first voltage to the first DC control line, and to apply a second voltage to the second DC control line; a first controlled amount of voltage applied by the controller to the first DC control line determines a first RF-SQUID set inductance, resulting in a first controlled inductance of the first microstrip inductor, and a second controlled amount of voltage applied by the controller to the second DC control line determines a second RF-SQUID set inductance, resulting in a second controlled inductance of the second microstrip inductor. The tunable bandstop filter can be tuned to attenuate a rejected frequency range associated with incoming radio frequency signals based on a first value of the first capacitor, the first controlled inductance of the first microstrip inductor, a second value of the second capacitor, and the second controlled inductance of the second microstrip inductor, to pass microwave signals that can be outside of the rejected frequency range through the cryogenic tunable bandstop filter device for interaction with a qubit.

The microwave signal can be generated by a microwave signal source controlled by the controller, and the cryogenic tunable bandstop filter can be coupled via an input contact to the microwave signal source to obtain the incoming radio frequency signals, and coupled via an output contact to output a filtered instance of the microwave signals to the qubit.

The input contact can be coupled to the microwave signal source via a phase shifter to obtain the incoming microwave signals as phase-shifted microwave signals.

The cryogenic tunable bandstop filter can be deployed within a dilution refrigerator at a temperature level of five Kelvin or below.

The incoming radio frequency signals can be a first group of incoming radio frequency signals, the microwave signals passed through the cryogenic tunable bandstop filter device can be first microwave signals, and the rejected frequency range can be a first rejected frequency range. The cryogenic tunable bandstop filter can be configured to obtain a second group of radio frequency signals. A third controlled amount of voltage applied to the first DC control line can determine a third RF-SQUID set inductance, resulting in a third controlled inductance of the first microstrip inductor, a fourth controlled amount of voltage applied to the second DC control line can determine a fourth RF-SQUID set inductance, resulting in a fourth controlled inductance of the second microstrip inductor, and the tunable bandstop filter can be tuned to attenuate a second rejected frequency range associated with an incoming second group of radio frequency signals based on the first value of the first capacitor, the third controlled inductance of the first microstrip inductor, the second value of the second capacitor, and the fourth controlled inductance of the second microstrip inductor, to pass second microwave signals that can be outside of the rejected second frequency range through the cryogenic tunable bandstop filter device for interaction with the qubit.

As can be seen, the technology described herein is directed towards a tunable bandstop filter with a frequency response achieved via sets of rf-SQUIDs tuned via voltages. The tunable bandstop filter is cryogenic compatible, ensuring that clear microwave qubit control signals can be passed through the bandstop filter. Note that the tunable bandstop filter can be used in higher (e.g., room) temperature environments. The tunable bandstop filter device ensures that only unwanted frequencies are attenuated, while desired signals pass through with minimal insertion loss.

The integration of rf-SQUID arrays to control the inductances of the inductors provides precise control over the frequency rejection band. The design offers real-time adjustment of the bandstop frequencies, enabling the filter to dynamically adapt to different noise sources or environmental changes that affect quantum systems. One example design efficiently integrates capacitors and inductors in a multi-layer Niobium-based superconducting fabrication process to achieve a compact layout. This approach leads to minimum thermal load, appropriate for quantum environments.

In one example implementation, the classical control system described herein, including the ADC, DAC, and HPC server/cluster, can monitor the quantum operations in real-time, to dynamically adjust control parameters based on feedback from the qubits, and thereby mitigate noise and optimize qubit performance without introducing additional noise or latency. This is in contrast to traditional designs for control in quantum circuits that do not adapt to dynamic changes in the quantum environment. Indeed, as errors develop over time, existing systems do not provide real-time adjustments to compensate for noise-related or other types of deviations, which causes the quantum system's performance to degrade over extended operations; qubit operations in existing systems are vulnerable to noise and signal drift, as errors are only reactively corrected after they have already adversely impacted the system. Instead, the technology described herein enables real-time detection and correction of signal issues including misalignments and noise outside of a desired frequency band, mitigating noise-related errors, which results in enhanced qubit coherence and improved fidelity in quantum gate operations.

The above description of illustrated embodiments of the subject disclosure, comprising what is described in the Abstract, is not intended to be exhaustive or to limit the disclosed embodiments to the precise forms disclosed. While specific embodiments and examples are described herein for illustrative purposes, various modifications are possible that are considered within the scope of such embodiments and examples, as those skilled in the relevant art can recognize.

In this regard, while the disclosed subject matter has been described in connection with various embodiments and corresponding Figures, where applicable, it is to be understood that other similar embodiments can be used or modifications and additions can be made to the described embodiments for performing the same, similar, alternative, or substitute function of the disclosed subject matter without deviating therefrom. Therefore, the disclosed subject matter should not be limited to any single embodiment described herein, but rather should be construed in breadth and scope in accordance with the appended claims below.

As used in this application, the terms “component,” “system,” “platform,” “layer,” “selector,” “interface,” and the like are intended to refer to a computer-related resource or an entity related to an operational apparatus with one or more specific functionalities, wherein the entity can be either hardware, a combination of hardware and software, software, or software in execution. As an example, a component can be an apparatus with specific functionality provided by mechanical parts operated by electric or electronic circuitry. As yet another example, a component can be an apparatus that provides specific functionality through electronic components without mechanical parts, the electronic components can comprise a processor therein to execute software or firmware that confers at least in part the functionality of the electronic components.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances.

While the embodiments are susceptible to various modifications and alternative constructions, certain illustrated implementations thereof are shown in the drawings and have been described above in detail. It should be understood, however, that there is no intention to limit the various embodiments to the specific forms disclosed, but on the contrary, the intention is to cover all modifications, alternative constructions, and equivalents falling within the spirit and scope.

In addition to the various implementations described herein, it is to be understood that other similar implementations can be used or modifications and additions can be made to the described implementation(s) for performing the same or equivalent function of the corresponding implementation(s) without deviating therefrom. Still further, multiple processing chips or multiple devices can share the performance of one or more functions described herein, and similarly, storage can be effected across a plurality of devices. Accordingly, the various embodiments are not to be limited to any single implementation, but rather are to be construed in breadth, spirit and scope in accordance with the appended claims.

What is claimed is:

1. A tunable bandstop filter, comprising:
a first microstrip inductor;
a first capacitor;
a first radio-frequency superconducting quantum interference device (RF-SQUID) set, the first RF-SQUID set being inductively coupled to the first inductor and inductively coupled to a first direct current (DC) control line;
a second microstrip inductor;
a second capacitor;
a second RF-SQUID set, the second RF-SQUID set being inductively coupled to the second inductor and inductively coupled to a second direct current (DC) control line;
wherein a first amount of voltage applied to the first DC control line inductively couples a first amount of magnetic flux to the first RF-SQUID set, to determine a first controlled inductance of the first microstrip inductor,
wherein a second amount of voltage applied to the second DC control line inductively couples a second amount of magnetic flux to the second RF-SQUID set, to determine a second controlled inductance of the second microstrip inductor, and
wherein a radio frequency (RF) signal input to the tunable bandstop filter results in a filtered instance of the RF signal output from the tunable bandstop filter, within a controlled frequency range based on a first capacitance value of the first capacitor, the first controlled inductance of the first microstrip inductor, a second capacitance value of the second capacitor, and the second controlled inductance of the second microstrip inductor.

2. The tunable bandstop filter of claim 1, wherein the RF signal comprises a microwave signal output from a microwave signal source and directed towards a qubit chain.

3. The tunable bandstop filter of claim 2, wherein the tunable bandstop filter and the qubit chain are deployed within a dilution refrigerator.

4. The tunable bandstop filter of claim 2, wherein the tunable bandstop filter and at least one qubit of the qubit chain are fabricated on a single chip.

5. The tunable bandstop filter of claim 2, wherein the tunable bandstop filter and the microwave signal source are deployed at room temperature.

6. The tunable bandstop filter of claim 1, wherein the first capacitor comprises a first multilayer metal-insulator-metal capacitor, and wherein the second capacitor comprises a second multilayer metal-insulator-metal capacitor.

7. The tunable bandstop filter of claim 6, wherein layers of the first multilayer metal-insulator-metal capacitor comprise niobium superconducting layers.

8. The tunable bandstop filter of claim 1, wherein the amount of voltage applied to the DC control line is controlled by a controller.

9. The tunable bandstop filter of claim 8, wherein the controller comprises a computing device comprising at least one processor and at least one memory.

10. The tunable bandstop filter of claim 8, wherein the radio frequency signal comprises a microwave signal directed towards a qubit, and wherein the computing device determines the first amount of voltage and determines the second amount of voltage based on monitoring interaction of a previous filtered instance of a previous microwave signal with the qubit.

11. A method, comprising:
controlling, by a system comprising at least one processor, a tunable bandstop filter device to attenuate a range of radio frequency signals, wherein the tunable bandstop filter device comprises a first capacitor coupled to a first tunable inductor, and a second capacitor coupled to a second tunable inductor, the controlling comprising:
applying a first amount of voltage to a first direct current (DC) control line to couple a first magnetic flux to a first radio-frequency superconducting quantum interference device (RF-SQUID) set that is inductively coupled to the first DC control line, and inductively coupled to the first inductor, to determine a first controlled inductance of the first inductor, and
applying a second amount of voltage to a second direct current (DC) control line to couple a second magnetic flux to a second RF-SQUID set that is inductively coupled to the second DC control line, and inductively coupled to the second inductor, to determine a second controlled inductance of the second inductor,
wherein a first capacitance value of the first capacitor and the first controlled inductance, and a second capacitance value of the second capacitor and the second controlled inductance, determine a filtered frequency range attenuated by the tunable bandstop filter device, to pass a radio frequency signal outside of the filtered frequency range through the tunable bandstop filter device.

12. The method of claim 11, wherein the radio frequency signal comprises a microwave signal directed towards a qubit, and wherein the controlling of the tunable bandstop filter device is performed by a computing device that monitors interaction of a microwave signal with the qubit.

13. The method of claim 11, wherein the filtered frequency range is a first filtered frequency range, wherein the radio frequency signal outside of the filtered frequency range is a first radio frequency signal outside of the first filtered frequency range, wherein the controlling of the tunable bandstop filter device is a first controlling operation to pass the first radio frequency signal outside of the filtered frequency range through the tunable bandstop filter device, and further comprising:
in a second controlling operation, controlling, by the system, the tunable bandstop filter device, the second controlling operation comprising:
applying a third amount of voltage to a first direct current (DC) control line to couple a third magnetic flux to the first RF-SQUID set that is inductively coupled to the first DC control line, and inductively coupled to the first inductor, to determine a third controlled inductance of the first inductor, and
applying a fourth amount of voltage to the second direct DC control line to couple a fourth magnetic flux to the RF-SQUID set that is inductively coupled to the second DC control line, and inductively coupled to the second inductor, to determine a fourth controlled inductance of the second inductor,
wherein the first capacitance value of the first capacitor, the third controlled inductance of the first inductor, the second capacitance value of the second capacitor, and the fourth controlled inductance of the second inductor, determine a second frequency range attenuated by the tunable bandstop filter device, to pass a second radio frequency signal outside of the second filtered frequency range through the tunable bandstop filter device.

14. The method of claim 13, wherein the first radio frequency signal comprises a microwave signal directed towards a qubit.

15. The method of claim 14, wherein the second controlling operation of the tunable bandstop filter device is performed by a computing device that monitors interaction of the first microwave signal with the qubit, and wherein the second controlling operation is based on monitoring, by the system, the interaction of the first microwave signal, outside of the filtered frequency range and passed through the tunable bandstop filter with the qubit, to determine the third amount of voltage and the fourth amount of voltage.

16. A system, comprising:
a cryogenic tunable bandstop filter device, comprising:
a first capacitor,
a first microstrip inductor electrically coupled to the first capacitor;
a first radio-frequency superconducting quantum interference device (RF-SQUID) set inductively coupled to the first microstrip inductor;
a second capacitor,
a second microstrip inductor electrically coupled to the first capacitor;
a second RF-SQUID set inductively coupled to the second microstrip inductor; and
a controller configured to apply a first voltage to the first DC control line, and to apply a second voltage to the second DC control line,
wherein a first controlled amount of voltage applied by the controller to the first DC control line determines a first RF-SQUID set inductance, resulting in a first controlled inductance of the first microstrip inductor, wherein a second controlled amount of voltage applied by the controller to the second DC control line determines a second RF-SQUID set inductance, resulting in a second controlled inductance of the second microstrip inductor,
wherein the tunable bandstop filter is tuned to attenuate a rejected frequency range associated with incoming radio frequency signals based on a first value of the first capacitor, the first controlled inductance of the first microstrip inductor, a second value of the second capacitor, and the second controlled inductance of the second microstrip inductor, to pass microwave signals that are outside of the rejected frequency range through the cryogenic tunable bandstop filter device for interaction with a qubit.

17. The system of claim 16, wherein the microwave signal is generated by a microwave signal source controlled by the controller, and wherein the cryogenic tunable bandstop filter is coupled via an input contact to the microwave signal source to obtain the incoming radio frequency signals, and coupled via an output contact to output a filtered instance of the microwave signals to the qubit.

18. The system of claim 17, wherein the input contact is coupled to the microwave signal source via a phase shifter to obtain the incoming microwave signals as phase-shifted microwave signals.

19. The system of claim 16, wherein the cryogenic tunable bandstop filter is deployed within a dilution refrigerator at a temperature level of five Kelvin or below.

20. The system of claim 16, wherein the incoming radio frequency signals are a first group of incoming radio frequency signals, wherein the microwave signals passed through the cryogenic tunable bandstop filter device are first microwave signals, wherein the rejected frequency range is a first rejected frequency range,
wherein the cryogenic tunable bandstop filter is configured to obtain a second group of radio frequency signals,
wherein a third controlled amount of voltage applied to the first DC control line determines a third RF-SQUID set inductance, resulting in a third controlled inductance of the first microstrip inductor,
wherein a fourth controlled amount of voltage applied to the second DC control line determines a fourth RF-SQUID set inductance, resulting in a fourth controlled inductance of the second microstrip inductor, and
wherein the tunable bandstop filter is tuned to attenuate a second rejected frequency range associated with an incoming second group of radio frequency signals based on the first value of the first capacitor, the third controlled inductance of the first microstrip inductor, the second value of the second capacitor, and the fourth controlled inductance of the second microstrip inductor, to pass second microwave signals that are outside of the rejected second frequency range through the cryogenic tunable bandstop filter device for interaction with the qubit.
